(19) United States
(12) Patent Application Publication
(10) Pub. No.: US 2012/0085959 A1
(43) Pub. Date: Apr. 12, 2012

(54) USE OF UNSATURATED HYDROFLUOROCARBONS

(75) Inventors: Ercan Uenveren, Hannover (DE); Christoph Meurer, Hannover (DE)

(73) Assignee: SOLVAY FLUOR GMBH, Hannover (DE)

(21) Appl. No.: 13/203,611

(22) PCT Filed: Mar. 5, 2010
(86) PCT No.: PCT/EP2010/052819

§ 371 Date: Dec. 2, 2011

(30) Foreign Application Priority Data
Mar. 6, 2009 (EP) 09003296.2

(51) Int. Cl. C08J 9/14; A62D 1/00; C09K 5/04; C09K 13/00; C11D 7/50; H01L 21/302; C09K 3/30; C09K 3/00; F25D 31/00; F28D 15/00; A62C 2/00; C08G 71/04; C11D 17/00

(52) U.S. Cl. 252/2; 521/131; 252/67; 252/79.1; 510/461; 510/408; 516/8; 516/12; 62/119; 165/104.21; 169/46; 438/689; 257/E21.214

(57) ABSTRACT

Use of certain hydrofluoroalkenes for foam blowing, solvent cleaning, refrigeration, as etching gas for semiconductor etching or chamber cleaning, heat transfer, fire extinguishing and for the production of aerosols.

### CROSS-REFERENCE TO RELATED APPLICATIONS

This application claims priority to European Patent Application No. 09003296.2 filed Mar. 6, 2009 this application being incorporated herein by reference in their entirety for all purposes.

### DESCRIPTION

The present invention relates to the use of certain unsaturated hydrofluorocarbons for foam blowing, solvent cleaning, refrigeration, as etching gas for semiconductor etching or chamber cleaning, heat transfer, fire extinguishing and for the production of aerosols. Furthermore, the present invention relates to methods of using compositions comprising certain unsaturated hydrofluorocarbons for applications as mentioned above.

WO 2009/019219 describes methods of using certain compounds, including, inter alia, hydrofluorocarbons for useful applications such as foam blowing, solvent cleaning, and refrigeration, as etching gas for semiconductor etching or chamber cleaning, heat transfer, fire extinguishing and production of aerosols.

Foams have found widespread commercial use in a variety of different applications. In general, the manufacture of foams requires the use of so called blowing agents, which are necessary for the expansion into the final structure. Historically, chlorofluorocarbons (so called CFC's, e.g. trifluoromethane, also known as CFC-11) or hydrochlorofluorocarbons (also known as HCFC's, e.g. 1,1,-dichloro-1-fluoroethane or HCFC-141b) were widely used as foam blowing agents e.g. for polyurethane foams. Known blowing agents for polystyrene foams are dichlorodifluoromethane (CFC-12) or chlorodifluoromethane (HCFC-22) or blends of various HCFC's. Other CFC's or HCFC's have been used in the manufacture of phenolic foams or other special types of foams as closed-cell foams or open-cell foams or multimodal foams respectively.

In general the CFC's produce foams exhibiting good thermal insulation, low flammability and good dimensional stability. However, due to the implications of chlorine-containing molecules like CFC's and HCFC's in the destruction of stratospheric ozone, the production and use of CFC's and HCFC's has been restricted by the so-called Montreal Protocol.

More recently, hydrofluorocarbons, so called HFC's have been used as substitutes for CFC's and HCFC's. Whereas these compounds have no detrimental influence on the stratospheric ozone, there are concerns due to their contribution to the greenhouse effect, i.e. they contribute to global warming. As a result thereof, HFC's have also come under scrutiny and their widespread use may be limited in the future.

WO 2007/053674 discloses methods for making foams using blowing agents comprising unsaturated fluorocarbons, and a significant number of different unsaturated hydrofluorocarbons is disclosed as suitable. The preferred unsaturated hydrofluorocarbons have the formula R¹CH═CHR², wherein R¹ and R² are, independently, C₁ to C₆ perfluoroalkyl groups. Optionally, a mixture of different unsaturated hydrofluorocarbons may be used.

WO 2004/096737 describes fluorobutenes and processes for the manufacture of the same. Specifically mentioned amongst the fluorobutenes are 2,4,4,4-tetrafluorobutene and (E)- and (Z)-1,1,1,3-tetrafluorobut-2-ene which are also named as HFC-1354 according to the commonly used nomenclature for halogenated hydrocarbons. Various processes for the manufacture of these compounds are described; however there is no indication as to the usability of these new compounds.

WO 2009/010472 discloses the preparation of halogen and hydrogen containing alkenes over metal fluoride catalysts, in particular specific types of metal fluoride catalysts with a high specific surface and a high Lewis acidity. The aforementioned HFC-1354 isomers are expressly mentioned as preferred products and example 9 refers to the manufacture of these compounds. There is no disclosure of specific applications where these compounds might be commercially used.

In view of the foregoing, there is a continuing need for new compositions useful for foam blowing, solvent cleaning, and refrigeration, as etching gas for semiconductor etching or chamber cleaning, heat transfer, fire extinguishing and for the production of aerosols.

It is an object of the present invention to provide new uses for certain hydrofluoroalkenes.

This object is achieved through the use of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336), for foam blowing, solvent cleaning, and refrigeration, as etching gas for semiconductor etching or chamber cleaning, heat transfer, fire extinguishing or for the production of aerosols.

The invention provides

a method for foam blowing wherein a polymeric foam is produced wherein a blowing agent is applied comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336), and

a method of solvent cleaning wherein items to be cleaned are contacted with a solvent comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336), and

a method for refrigeration wherein a refrigerant comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) is evaporated in the vicinity of a body to be cooled and thereafter is condensated, and

a method for producing heat wherein a composition comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) is condensed in the vicinity of a body to be heated and thereafter is evaporated, and

a method of etching a semiconductor wherein a semiconductor is contacted with an etching agent comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) which method is preferably plasma-assisted, and

a method for heat transfer wherein heat is transferred with a heat-transferring agent comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336), and

a method of extinguishing fire applying a fire extinguishing agent comprising or consisting of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336), and

a method of producing aerosols with a propellant wherein the propellant comprises or consists of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336).

Preferred HFC-1354 isomers are (Z)-1,1,1,3-tetrafluorobut-2-ene and 2,4,4,4-tetrafluorobut-1-ene.

These compounds are preferably obtained by the elimination of hydrogen fluoride from 1,1,1,3,3-pentafluorobutane (known as HFC-365mfc). The process disclosed in WO 2009/010472 yields a mixture of these various isomers, the molar ratio of which depends on the temperature used in the dehydrofluorination process. Details about the preferred catalysts for such dehydrofluorination of 1,1,1,3,3-pentafluorobutane and the respective reaction conditions for obtaining the product mixture referred to above can be taken from WO 2009/010472, to which reference is made herewith in this regard.

Alternatively, mixtures of the HFC-1354 isomers used herein can also be obtained in accordance with the various processes disclosed in WO 2004/096737, to which reference is made for further details.

The boiling points (under atmospheric pressure) for the tetrafluorobutenes used in accordance with the present invention are 18° C. for (E)-1,1,1,3-tetrafluorobut-2-ene, 29° C. for 2,4,4,4-tetrafluorobut-1-ene and 48° C. for (Z)-1,1,1,3-tetrafluorobut-2-ene.

The mixture of isomers obtained according to the processes disclosed in WO 2004/096737 or WO 2009/010472 can be used as such, it is preferred, however, to separate the isomers, e.g. by distillation before the use thereof as foam blowing agents.

(Z)-1,1,1,3-tetrafluorobut-2-ene and 2,4,4,4-tetrafluorobut-1-ene or their mixtures are preferably used according to the invention, the latter being particularly preferred.

The HFC-1354 isomers to be used in accordance with the present invention can also be used in combination with hexafluorobutenes (commonly referred to as HFC-1336).

Accordingly, a further aspect of the invention relates to mixtures of at least one compound selected from each of the following groups a) and b):

a) (Z)-1,1,1,3-tetrafluorobut-2-ene, (E)-1,1,1,3-tetrafluorobut-2-ene or 2,4,4,4-tetrafluorobut-1-ene, and
b) 1,1,1,4,4,4-hexafluorobut-2-ene, 1,1,2,3,4,4-hexafluorobut-2-ene, 1,1,1,3,4,4-hexafluorobut-2-ene and 1,1,1,2,4,4-hexafluorobut-2-ene.

Preferred are mixtures containing as compound of group a)

(Z)-1,1,1,3-tetrafluorobut-2-ene and 2,4,4,4-tetrafluorobut-1-ene, with the latter one being especially preferred.

Preferred compound of group b) (the HFC-1336 isomers) is 1,1,1,4,4,4-hexafluorobut-2-ene.

Azeotropic mixtures of HFC-1354 and HFC-1336 isomers in certain cases have proven advantageous in the application in accordance with the instant invention. Azeotropic mixtures have the advantage that the composition of the liquid and the vapor phase are identical and thus they behave, as far as the transition liquid-vapor is concerned, as a pure product (showing only one boiling point) in this regard, which is beneficial in a number of applications.

However, non-azeotropic mixtures are also suitable. The mixture ratio of the different hydrofluorocarbons is not subject to particular limitations and can be chosen broadly.

Thus, mixtures containing 10-90, preferably 20-80 and particularly preferred 30 to 70% by weight of HFC-1354 and respectively 10-90, preferably 20-80 and particularly 30-79% by weight of HFC-1336 isomers can be used (the percentages given in % by weight, based on the total weight of the hydrofluoroalkenes).

According to a first embodiment of the present invention (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) are used for foam blowing.

The types of foam which can be manufactured using the mentioned hydrofluorobutenes or mixtures thereof with other unsaturated hydrofluorocarbons, in particular with hexafluorobutenes, cover a broad range.

As a first group reference is made to polyurethane foams, which are generally prepared by combining and reacting an isocyanate with a polyol in the presence of a blowing or expanding agent and auxiliary chemicals added to control and modify both the polyurethane reaction itself and the properties of the final polymer. For processing convenience these two materials can be premixed into two non-reacting parts typically referred to as the “A-side” and the “B-side”.

The term “B-side” is intended to mean polyol or polyol containing mixture. A polyol containing mixture usually includes the polyol, the blowing or expanding agent and auxiliary chemicals, like catalysts, surfactants, stabilizers, chain extenders, cross-linkers, water, fire retardants, smoke suppressants, pigments, colouring materials, fillers, etc.

The term “A-side” is intended to mean isocyanate or isocyanate containing mixture. An isocyanate containing mixture may include the isocyanate, the blowing or expanding agent and auxiliary chemicals, like catalysts, surfactants, stabilizers, chain extenders, cross-linkers, water, fire retardants, smoke suppressants, pigments, colouring materials, fillers, etc.

To prepare the foam, appropriate amounts of A-side and B-side are then combined to react.

When preparing a foam by such a process, it is generally preferred to employ a minor amount of a surfactant to stabilize the foaming reaction mixture until it cures. Such surfactants may comprise a liquid or solid organosilicon compound. Other, less preferred surfactants include polyethylene glycol ethers of long chain alcohols, tertiary amine or alkanolamine salts of long chain alkyl acid sulfate esters, alkyl sulfonic esters and alkyl arylsulfonic acids. The surfactants are employed in amounts sufficient to stabilize the foaming reaction mixture against collapse and to prevent the formation of large, uneven cells. About 0.2 to about 5 parts or even more of the surfactant per 100 parts by weight of polyol are usually sufficient.

One or more catalysts for the reaction of the polyol with the polyisocyanate may also be used. Any suitable urethane catalyst may be used, including tertiary amine compounds and organometallic compounds. Such catalysts are used in an amount which measurably increases the rate of reaction of the polyisocyanate. Typical amounts are about 0.1 to about 5 parts of catalyst per 100 parts by weight of polyol.

Useful flame retardants include, for example, tri(2-chloroethyl)phosphate, tri(2-chloropropyl)phosphate, tri(2,3-dibromopropyl)phosphate, tri(1,3-dichloropropyl)phosphate, triethylphosphate, ethyl diethyl phosphonate, diammonium phosphate, various halogenated aromatic compounds, antimony oxide, aluminum trihydrate, polyvinyl chloride, brominated polyols and the like.

The methods of forming a foam generally comprise providing a blowing agent composition containing the unsaturated hydrofluorobutenes, optionally together with other unsaturated hydrofluorobutenes, adding (directly or indirectly) the blowing agent composition to a foamable composition, and reacting the foamable composition under the conditions effective to form a foam or cellular structure. Any of the methods well known in the art, such as those described in “Polyurethanes Chemistry and Technology,” Volumes I and II, Saunders and Frisch, 1962, John Wiley and Sons, New York, N.Y., which is incorporated herein by reference, may be used or adapted for use in accordance with the foam embodiments.

Polyisocyanate-based foams are prepared, e.g., by reacting at least one organic polyisocyanate with at least one active hydrogen-containing compound in the presence of the bowing agent composition described herein-above.

An isocyanate reactive composition can be prepared by blending at least one active hydrogen-containing compound with the blowing agent composition. Advantageously, the blend contains at least 1 and up to 50, preferably up to 25 weight percent of the blowing agent composition, based on the total weight of active hydrogen-containing compound and blowing agent composition.

Active hydrogen-containing compounds include those materials having two or more groups which contain an active hydrogen atom which reacts with an isocyanate. Preferred among such compounds are materials having at least two hydroxyl, primary or secondary amine, carboxylic acid, or thiol groups per molecule. Polyols, i.e., compounds having at least two hydroxyl groups per molecule, are especially preferred due to their desirable reactivity with polyisocyanates.

Additional examples of suitable active hydrogen containing compounds can be found in U.S. Pat. No. 6,590,005, incorporated herein by reference. For example, suitable polyester polyols include those prepared by reacting a carboxylic acid and/or a derivative thereof or a polycarboxylic anhydride with a polyhydric alcohol. The polycarboxylic acids may be any of the known aliphatic, cycloaliphatic, aromatic, and/or heterocyclic polycarboxylic acids and may be substituted, (e.g., with halogen atoms) and/or unsaturated. Examples of suitable polycarboxylic acids and anhydrides include oxalic acid, malonic acid, glutaric acid, pimelic acid, succinic acid, adipic acid, suberic acid, azelaic acid, sebacic acid, phthalic acid, isophthalic acid, terephthalic acid, trimellitic acid, trimellitic acid anhydride, pyromellitic dianhydride, phthalic acid anhydride, tetrahydrophthalic acid anhydride, hexahydrophthalic acid anhydride, endomethylene tetrahydrophthalic acid anhydride, glutaric acid anhydride acid, maleic acid, maleic acid anhydride, fumaric acid, and dimeric and trimeric fatty acids, such as those of oleic acid which may be in admixture with monomeric fatty acids. Simple esters of polycarboxylic acids may also be used such as terephthalic acid dimethylester, terephthalic acid bisglycol and extracts thereof. The polyhydric alcohols suitable for the preparation of polyester polyols may be aliphatic, cycloaliphatic, aromatic, and/or heterocyclic. The polyhydric alcohols optionally may include substituents which are inert in the reaction, for example, chlorine and bromine substituents, and/or may be unsaturated. Suitable amino alcohols, such as monoethanolamine, diethanolamine or the like may also be used. Examples of suitable polyhydric alcohols include ethylene glycol, propylene glycol, polyoxyalkylene glycols (such as diethylene glycol, polyethylene glycol, dipropylene glycol and polypropylene glycol), glycerol and trimethylolpropane.

Suitable additional isocyanate-reactive materials include polyether polyols, polyester polyols, polyhydroxy-terminated acetal resins, hydroxyl-terminated amines and polyamines, and the like. These additional isocyanate-reactive materials include hydrogen terminated polythioethers, polyamides, polyester amides, polycarbonates, polyacetals, polyolefins, polysiloxanes, and polymer polyols.

Other Polyols include alkylene oxide derivatives of Mannich condensates, and aminoalkylpiperazine-initiated polyethers as described in U.S. Pat. Nos. 4,704,410 and 4,704,411. The low hydroxyl number, high equivalent weight alkylene oxide adducts of carbohydrate initiators such as sucrose and sorbitol may also be used.

In the process of making a polyisocyanate-based foam, the polyol(s), polyisocyanate and other components are contacted, thoroughly mixed and permitted to expand and cure into a cellular polymer. The particular mixing apparatus is not critical, and various types of mixing head and spray apparatus are conveniently used. It is often convenient, but not necessary, to preblend certain of the raw materials prior to reacting the polyisocyanate and active hydrogen-containing components. For example, it is often useful to blend the polyol(s), blowing agent, surfactant(s), catalyst(s) and other components except for polyisocyanates, and then contact this mixture with the polyisocyanate. Alternatively, all the components may be introduced individually to the mixing zone where the polyisocyanate and polyol(s) are contacted. It is also possible to pre-react all or a portion of the polyol(s) with the polyisocyanate to form a prepolymer.

The quantity of blowing agent composition employed when preparing a foam is sufficient to give a desired density to the foam. Advantageously, sufficient blowing agent is employed to provide a polyurethane foam having an overall density of from about 10 to about 500, preferably from about 18 to about 100 kg/m³.

It is often convenient to pre-blend the blowing agent composition with the active hydrogen-containing compound before contacting the resulting blend with the polyisocyanate. It is also possible to simultaneously blend together the polyisocyanate, active hydrogen-containing compound and blowing agent composition in one operation resulting in the production of polyisocyanate-based foam. Preferably the blowing agent composition is blended with the active hydrogen-containing compound before contacting with the polyisocyanate.

A premix comprising or consisting of polyol, blowing agent and optionally at least one auxiliary chemical, like catalysts, surfactants, stabilizers, chain extenders, cross-linkers, water, fire retardants, preferably an organic phosphate, especially triethyl phosphate, smoke suppressants, pigments, colouring materials, fillers, is another aspect of the present invention. The preferred amounts of the components are given above. The organic phosphate is contained in the premix in an amount of about 10 to 20% by weight of the total weight of the premix.

The rigid closed-cell celled polyisocyanate-based foams are useful in spray insulation, as foam-in-place appliance foams, rigid insulating board stock, or in laminates.

In addition, according to certain embodiments, the blowing agents are used to blow thermoplastic foams, such a polystyrene, polyethylene foams, including low-density polyethylene foams, or polypropylene foams. Any of a wide range of conventional methods for blowing such thermoplastic foams can be adapted for use herein.

Another embodiment provides a foamable composition comprising thermoplastic polymers, such as polystyrene, polyethylene (PE), preferably low density PE, or polypropylene (PP).

The thermoplastic foam bodies are conveniently produced by using conventional equipment comprising an extruder and associated means for (1) melting the resin; (2) homogeneously blending the blowing agent composition with the melt to form a plasticized mass at nonfoaming temperatures and pressures; (3) passing the plasticized mass at a controlled rate, temperature and pressure through a die having a desired shape, e.g., slit die for producing rectangular slabs of foam board having desired thickness and surface area, into an expansion zone; (4) allowing the extrudate to foam in the expansion zone maintainable at suitable temperatures and low pressures; (5) maintaining the expanding extrudate under such temperatures and pressures for a time sufficient for the viscosity of the extrudate to increase such that the cell size and density of the foam remain substantially unchanged and substantially free of ruptured cells at ambient temperature; e.g., 25° C. and atmospheric pressure; and (6) recovering the extruded foam body.

When preparing foams, it is often desirable to add a nucleating agent or other additives into the resin. Nucleating agents serve primarily to increase cell count and decrease cell size in the foam, and may be used in an amount of about 0.1 to about 10 parts by weight per 100 parts by weight of the resin. Typical nucleating agents comprise at lease one member selected from the group consisting of talc, sodium bicarbonate-citric acid mixtures, calcium silicate, carbon dioxide, among others.

In one aspect, the foaming amount of the blowing agent is in the range of from about 1 to about 30 weight percent based on the total weight of the resin plus blowing agent mixture, typically about 2 to 20 weight percent, and normally about 2 to about 10 weight percent. The lower the concentration of blowing agent, the greater the density of the resulting foam. The proper amount of blowing agent or resultant characteristics of the foam for any desired end-use is readily determined by a skilled person in this art. The resin is melted at a temperature of about 200 to about 235° C. depending upon the grade employed, and at nonfoaming pressures of about 4,1 MPa or higher. The plasticized resin-blowing agent mixture is cooled under nonfoaming pressure to a temperature of about 115 to 150° C., normally 130° C., and extruded into the expansion zone at or below ambient temperature and at or below atmospheric pressure.

Representative foamed products that can be made according to the present invention are for example: (1) polystyrene foam sheet for the production of disposable thermoformed packaging materials; e.g., as disclosed U.S. Pat. No. 5,204,169; (2) extruded polystyrene foam boards for use as residential and industrial sheathing and roofing materials; (3) expandable foams in the form of large billets. Such foamed products are more fully described by Stockdopole and Welsh in the Encyclopedia of Polymer Science and Engineering, vol. 16, pages 193-205, John Wiley & Sons, 1989.

A preferred use in accordance with the present invention is the manufacture of polyurethane foams, in particular thermoset polyurethane foams. It is especially preferred to prepare a polyurethane foam, especially a rigid polyurethane foam, wherein (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) are used as foam blowing agent.

The present invention provides blowing agent compositions useful in foamable compositions having a reduced global warming potential (GWP) compared to known blowing agent compositions while at the same time maintaining good thermal insulation properties, low flammability and excellent dimensional stability.

Mixtures of HFC-1354 isomers and HFC-1336 isomers as described hereinbefore have proven advantageous in some cases as, compared to HFC-1354 isomers alone, the flammability behavior is improved and the blend exhibits a higher blowing efficiency compared to its single components, i.e. less blowing agent is overall needed. This is particularly applicable in the use for the foam blowing of polyurethane foams of the type as described hereinbefore.

Global warming potentials (GWPs) are an index for estimating global warming contribution due to atmospheric emission of a kilogram of a particular greenhouse gas compared to emission of a kilogram of carbon dioxide. GWP can be calculated for different time horizons showing the effect of atmospheric lifetime for a given gas. The GWP for the 100 year horizon is commonly the value referred.

A high GWP blowing agent would be any compound capable of functioning as a blowing agent having a GWP at the 100 year time horizon of about 1000 or greater, alternatively 500 or greater, 150 or greater, 100 or greater, or 50 or greater.

In accordance with the present invention blowing compositions are provided that have zero or low ozone depletion potential and low global warming potential (GWP). The hydrofluorobutenes or their mixtures with hexafluorobutenes used according to the present invention will have global warming potentials that are less than many hydrofluorocarbon blowing agents or foamable compositions currently in use. Typically, a GWP of less than about 25 is to be expected. One aspect of the present invention is to provide a blowing agent with a global warming potential of less than 1000, preferably less than 500, more preferred less than 150 or better less than 100, or most preferred less than 50. Another aspect of the present invention is to reduce the net GWP of foamable compositions by adding fluoroolefins to said mixtures.

The present invention further relates to a method for lowering the GWP of the methods for manufacturing open, closed and multi-modal foams, said method comprising combining at least one fluoroolefin of the present invention with a resin (for thermoplastic foams) or into a B-side mixture (thermoplastic) to produce a foamable composition with a GWP of preferably less than 25. The

GWP of may be determined that the GWP of a mixture or combination of compounds may be calculated as a weighted average of the GWP for each of the pure compounds.

The foamable compositions with the blowing agents according to this invention also preferably have an Ozone Depletion Potential (ODP) of not greater than 0.05, more preferably not greater than 0.02 and even more preferably about zero. As used herein, “ODP” is as defined in “The Scientific Assessment of Ozone Depletion, 2002, A report of the World Meteorological Association's Global Ozone Research and Monitoring Project.

Foam blowing agents have preferably an atmospheric boiling point equal to or higher than 0° C., preferably equal to or higher than 20° C. and further preferably an atmospheric boiling point equal to or lower than 55° C., preferably equal to or lower than 50° C.

The content of the compounds used in accordance with the present invention in the foam blowing agent compositions is generally equal to or more than 10% by weight relative to the weight of the foam blowing agent. Often this content is equal to or more than 30% by weight and preferably equal to or more than 50% by weight. In some embodiments, the content of the compounds to be used in accordance with the invention in the foam blowing agent can be equal to or lower than 90% by weight relative to the weight of the foam blowing agent. Other typical contents in these embodiments are equal to or lower than 80% by weight or even equal to or lower than 75% by weight.

Alternatively, the foam blowing agent can consist or consist essentially of the compounds used in accordance with the present invention.

The foam blowing agent can further comprise non-fluoro organic co-blowing agents, in particular hydrocarbons.

Suitable hydrocarbons which can be used in the compositions may be linear, branched or cyclic and generally contain 3, 4, 5, 6, 7, 8, 9, 10, 11 or 12 carbon atoms. Hydrocarbons comprising at least 5 carbon atoms are suitable for use. The hydrocarbons preferably comprise at least 6 carbon atoms. Among the alkanes or alkenes, compounds comprising from 5 to 12 carbon atoms are preferred. n-Hexane, n-heptane and n-octane are suitable for use. Among the aromatic hydrocarbons which are preferred are those comprising at least one alkyl substituent on a benzene ring. Toluene, 1,2-xylene, 1,3-xylene, 1,4-xylene or mixtures thereof are most particularly preferred.

According to a second aspect of the invention, (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) are used for solvent cleaning.

The term solvent cleaning as used herein comprises cleaning a surface by contacting said surface with a solvent comprising at least one compound selected from the compounds or mixtures mentioned above.

In the use for solvent cleaning the solvent has generally a GWP₁₀₀ of less than 150, preferably equal to or less than 120, more preferably equal to or less than 80 and most preferably equal to or less than 50.

A solvent used for solvent cleaning has generally an atmospheric boiling point equal to or higher than 20° C., preferably equal to or higher than 25° C. and more preferably equal to or higher than 35° C. In the first aspect of the invention the solvent has generally an atmospheric boiling point equal to or lower than 100° C., preferably equal to or lower than 80° C. and more preferably equal to or lower than 60° C.

In this embodiment, the content of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) in the solvent is generally equal to or more than 1% by weight relative to the weight of the solvent. Often this content is equal to or more than 10% by weight, preferably equal to or more than 30% by weight. In some embodiments, the content of the compounds described hereinbefore in the solvent can be about 100% by weight relative to the weight of the solvent. Other typical contents in these embodiments are, for example equal to or less than 99% by weight, equal to or less than 98% by weight or even equal to or lower than 75% by weight.

According to a preferred embodiment, the solvent can consist or consist essentially of a compound as given above.

In addition, the solvent can further comprise for example non-fluoro organic solvents in addition to anyone of the fluorinated compounds described before. Suitable compounds of such type are disclosed for example in WO 2009/019219, to which reference is made herewith.

The solvent cleaning process can be one step in a process comprising several cleaning steps. For example, items can in a first step be treated by high boiling hydrocarbons, for example, n-octane, toluene or xylene, and in a further, preferably a second step, the compounds in accordance with the present invention are applied.

In a further embodiment the surface can be dried. In that case, the solvent comprising the compounds or mixtures of compounds to be used in accordance with the present invention functions as a drying agent. A drying agent is used, for example, in the electronics or electromechanical industry or optionally the cosmetic industry when it is desired to remove the water adsorbed onto a solid surface of an object after an aqueous treatment. The aqueous treatment can consist, for example, of a cleaning operation, optionally in the presence of a surfactant. Generally, after the aqueous treatment, the object is immersed in a drying agent in the boiling state comprising a surfactant, and the surfactant which adheres to the surface of the object is then removed in a washing bath.

Surfactants of the alkylbenzenesulphonate type are generally preferred. Such surfactant often comprise an alkyl chain comprising from 4 to 22 and preferably from 10 to 14 carbon atoms. Dodecylbenzenesulphonate salts, in particular the salts of a quaternary amine, give good results. Isopropylammonium dodecylbenzenesulphonate is particularly preferred.

In a particular aspect, the solvent comprising the compounds to be used in accordance with the present invention is used as a water displacement agent.

In another embodiment, the surface is degreased. In this case, the solvent functions as a degreasing solvent.

A degreasing solvent is used, for example, in the electronics or electromechanical industry to remove the grease adsorbed in particular onto metal components machined with grease. Generally, a component to be degreased is immersed in a bath of boiling degreasing solvent. The compositions according to the invention comprising a non-fluoro organic solvent of high polarity, such as alkanols, in particular methanol or ethanol and/or those which comprise a chlorohydrocarbon, are particularly suitable as degreasing solvents.

In yet another embodiment the solvent may be used used to remove flux residues. For example, flux residues of soldered electric components are defluxed.

Other embodiments of the present invention relate to the use of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) for refrigeration, as etching gas for semiconductor etching or chamber cleaning, heat transfer, fire extinguishing and for the production of aerosols.

When used as etching gas, in particular for semiconductor etching or chamber cleaning the atmospheric boiling point of the compound or the mixture of compounds used in accordance with the present invention is equal to or lower than 30° C.

Etching can for example be performed in an Inductive Coupled Plasma Source (ICP) etch reactor or in a Capacitively Coupled Plasma Source (CCP) reactor which is available from Applied Materials. A general process may be described as follows: A self-aligned contact (SAC) is formed as described on page 3 of WO 2000/302168. A polysilicon gate layer, a tungsten silicide barrier and glue layer, and a silicon nitride cap layer are deposited and photolithographically formed into two closely related spaced gate structures having a gap there between. Then, a silicon nitride layer is deposited via CVD on the structure, and dopant ions are implanted. A dielectric SiO₂ layer is deposited over the structure, a photoresist layer is deposited over the over the oxide layer and photographically defined using light with a wavelength of 193 nm into a mask. Then, using (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) optionally mixed respectively diluted with a noble gas, e.g. argon, and argon, delivered into the plasma reactor, the SiO₂ layer is etched.

Instead of SiO₂ layers low-k dielectric layers or ultra-low-k dielectric layers may also be used.

In a further embodiment, the present invention relates to the use of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) as carrier fluid to depose layers of material, for example organic materials and in particular greases on a surface.

The use of (Z)-1,1,1,3-tetrafluorobut-2-ene, (E)-1,1,1,3-tetrafluorobut-2-ene or 2,4,4,4-tetrafluorobut-1-ene (commonly referred to as HFC-1354) or mixtures thereof or mixtures of one or more of these compounds with hexafluorobutenes (commonly referred to as HFC 1336) for heat transfer, fire extinguishing and in the manufacture of aerosols are further aspects of the invention.

Should the disclosure of any of the patents, patent applications, and publications that are incorporated herein by reference conflict with the present description to the extent that it might render a term unclear, the present description shall take precedence.

The following examples are intended to explain the invention further without limiting it.

### EXAMPLE 1

### Manufacture of a Polyurethane Foam

1.1. Manufacture of a mixture of 2,4,4,4-tetrafluorobut-1-ene and 1,1,1,4,4,4-hexafluorobut-2-ene

50 parts by weight of 2,4,4,4-tetrafluorobut-1-ene and 50 parts by weight of 1,1,1,4,4,4-hexafluorobut-2-ene are mixed to give a blowing agent mixture.

### 1.2. Manufacture of a Premix

A polyol component consisting of 40 parts by weight of an ethylendiamine/propylenoxide polyether (OH number 480), 60 parts by weight of a sorbitol/glycerine/propylenoxide polyether (OH number 490), 1 part by weight of a foam stabilizer (DC193 of Dow Corning Corp.) and 1.5 parts by weight of dimethyl cyclohexylamine is mixed with the blowing agent mixture of example 1.1 in an amount of 30 parts by weight relative to the polyol component.

### 1.3. Manufacture of the PU Foam

The polyol mixture of example 1.2 is mixed with diphenylmethane diisocyanate as cyanate component; the diisocyanate is applied in an amount which is 10% by weight higher than stoichiometrically needed.

The PUR foams are manufactured in a low pressure apparatus with an output of about 8 kg/minute. A dynamic mixer (pouring machine) is used for mixing.

A PUR hard foam containing fine cells is produced.

1. A method for utilizing (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes, said method being selected from the group consisting of:
a method of foam blowing wherein a polymeric foam is produced and wherein a blowing agent is applied comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes;
a method of solvent cleaning wherein items to be cleaned are contacted with a solvent comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes;
a method for refrigeration wherein a refrigerant comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes is evaporated in the vicinity of a body to be cooled and thereafter is condensated;
a method for producing heat wherein a composition comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes is condensed in the vicinity of a body to be heated and thereafter is evaporated;
a method of etching a semiconductor, wherein a semiconductor is contacted with an etching agent comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes;
a method for heat transfer wherein heat is transferred with a heat-transferring agent comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes;
a method of extinguishing fire comprising applying a fire extinguishing agent comprising or consisting of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes; and
a method of producing aerosols with a propellant wherein the propellant comprises or consists of (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes.

2. Use of The method according to claim 1 wherein 2,4,4,4-tetrafluorobut-1-ene or a mixture thereof with hexafluorobutenes in accordance with claim 1 is utilized.

3. A method of using (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one of these compounds with hexafluorbutenes for foam blowing, solvent cleaning, refrigeration, as etching gas for semiconductor etching or chamber cleaning, heat transfer, fire extinguishing and the production of aerosols.

4. The method in accordance with claim 3 for producing a polymer foam wherein a blowing agent is used which comprises (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one of these compounds with hexafluorbutenes as components of a blowing agent composition.

5. The method in accordance with claim 3 for cleaning a surface which comprises contacting said surface with a solvent comprising (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorbutenes.

6. The method in accordance with claim 3 wherein 2,4,4,4-tetrafluorobut-1-ene or a mixture thereof with hexafluorobutenes is used.

7. A mixture of at least one compound selected from each of the following groups a) and b):
a) (Z)-1,1,1,3-tetrafluorobut-2-ene, (E)-1,1,1,3-tetrafluorobut-2-ene or 2,4,4,4-tetrafluorobut-1-ene, and
b) 1,1,1,4,4,4-hexafluorobut-2-ene, 1,1,2,3,4,4-hexafluorobut-2-ene, 1,1,1,3,4,4-hexafluorobut-2-ene and 1,1,1,2,4,4-hexafluorobut-2-ene.

8. The mixture in accordance with claim 7, wherein the components of the mixture form an azeotrope.

9. The mixture in accordance with claim 7, wherein said component a) is 2,4,4,4-tetrafluorobut-1-ene.

10. The mixture in accordance with claim 7, wherein said component b) is 1,1,1,4,4,4-hexafluorobut-2-ene.

11. A premix comprising polyol, a blowing agent and optionally at least one auxiliary chemical, wherein the blowing agent comprises (Z)-1,1,1,3-tetrafluorobut-2-ene, (E)-1,1,1,3-tetrafluorobut-2-ene, 2,4,4,4-tetrafluorobut-1-ene, mixtures thereof, or mixtures of one or more of these compounds with hexafluorobutenes.

12. The premix of claim 11, wherein the at least one auxiliary chemical is selected from the group consisting of catalysts, surfactants, stabilizers, chain extenders, cross-linkers, water, fire retardants, smoke suppressants, pigments, coloring materials, and fillers.
